(19) United States
(12) Patent Application Publication
(10) Pub. No.: US 2019/0049803 A1
(43) Pub. Date: Feb. 14, 2019

(54) ACTIVE SWITCH ARRAY SUBSTRATE, MANUFACTURING METHOD THEREFOR SAME, AND DISPLAY DEVICE USING SAME

(71) Applicants: HKC Corporation Limited, Shenzhen City, Guangdong (CN); Chongqing HKC Optoelectronics Technology Co., Limited, Chongqing (CN)

(72) Inventor: Yu-Jen CHEN, Chongqing (CN)

(21) Appl. No.: 15/555,416

(22) PCT Filed: Jul. 3, 2017
(86) PCT No.: PCT/CN2017/091471

§ 371 Date: Sep. 1, 2017

(30) Foreign Application Priority Data
Mar. 20, 2017 (CN) 201710165143.1

(51) Int. Cl. G02F 1/1362; G02F 1/1335; G02F 1/1368; G02F 1/1339; H01L 27/12; G02F 1/1343

(52) U.S. Cl. CPC G02F 1/136286; G02F 1/133514; G02F 1/133512; G02F 1/1368; G02F 2201/123; H01L 27/124; H01L 27/1288; G02F 1/134363; G02F 1/1339

(57) ABSTRACT

This application provides an active switch array substrate, manufacturing method therefor, and a display device using same. The active switch array substrate includes: a first substrate, having an outer surface, where the outer surface has a black adhesive material; a plurality of gate lines, formed on the first substrate; a gate covering layer, formed on the first substrate and covering the gate lines; a plurality of data lines, formed on the gate covering layer; a first protection layer, formed on the gate covering layer and covering the data lines; a plurality of color filters (CFs), formed on the first protection layer and including a plurality of photoresist layers disposed in parallel; a second protection layer, formed on the CFs and covering the first protection layer; a pixel electrode layer, formed on the second protection layer, a plurality of light spacers, formed on the second protection layer and connected to the second protection layer; and an opaque matrix layer, formed on the outer surface of the first substrate, where the opaque matrix layer shields the gate lines.

### BACKGROUND

### Technical Field

This application relates to a manufacturing manner, and in particular, to an active switch array substrate, manufacturing method therefor, and a display device using same.

### Related Art

With the development of technologies, liquid crystal displays (LCD) having advantages such as power saving, no radiation, small volume, low power consumption, rectangular plane, high resolution, stable image quality become more popular. In particular, as various information products such as mobile phones, laptop computers, digital cameras, PDAs, liquid crystal screens become more popular, the demand of LCDs increases significantly. Therefore, active switch array liquid crystal displays (Thin Film Transistor Liquid Crystal Display, TFT-LCD) having a pixel design of high resolution and having advantages such as high image quality, high space-using efficiency, low power consumption, no radiation have gradually become a main stream of the market. An active switch array substrate is an important component for constructing an LCD.

The active switch array substrate includes an opposite substrate having a photoresist layer of red, green, and blue colors (RGB on CF), an active switch array substrate having an RGB photoresist layer on an in-plane switching liquid crystal panel (RGB on Array/In-Plane Switching, IPS mode), and an active switch array substrate having an RGB photoresist layer on a vertical alignment liquid crystal panel (RGB on Array/Vertical Alignment, VA mode). In this way, a pixel structure design of the active switch array substrate plays a key role to improve a pixel design of a resolution. In an LCD process of the related art, an RGB photoresist layer is disposed on a glass end of a color filter (CF), and movable mura (MM) of an image occurs as a result of frequent misalignment of upper and lower glasses. Therefore, MM of an image in an active switch array substrate process may be reduced by using an RGB photoresist layer, and cable load may be effectively reduced and an aperture ratio is improved. Advantages of the RGB photoresist layer are easily presented by being applied to a curved television.

### SUMMARY

To resolve the foregoing technical problem, an objective of this application is to provide an active switch array substrate, a method for manufacturing an active switch array substrate, and a display device using same, to reduce MM of a displayed image and an alignment accuracy error of upper and lower substrate glasses.

The objective of this application is achieved and the technical problem of this application is resolved by using the following technical solutions. An active switch array substrate provided according to this application comprises: a first substrate, having an outer surface, where the outer surface has a black adhesive material; a plurality of gate lines, formed on the first substrate; a gate covering layer, formed on the first substrate and covering the gate lines; a plurality of data lines, formed on the gate covering layer; a first protection layer, formed on the gate covering layer and covering the data lines; a plurality of CFs, formed on the first protection layer and comprising a plurality of photoresist layers disposed in parallel; a second protection layer, formed on the CFs and covering the first protection layer; a pixel electrode layer, formed on the second protection layer; a plurality of light spacers, formed on the second protection layer and connected to the second protection layer; and an opaque matrix layer, formed on the outer surface of the first substrate, where the opaque matrix layer shields the gate lines.

The technical problem of this application may further be resolved by using the following technical solutions.

In an embodiment of this application, the opaque matrix layer is made of an insulating black ink.

In an embodiment of this application, the light spacer has a protrusion shape with a narrow top and a wide bottom.

In an embodiment of this application, the black adhesive material of the outer surface of the first substrate is the same as the material of the opaque matrix layer, to cover a frame circuit.

Another objective of this application is to provide a method for manufacturing an active switch array substrate, comprising: providing a first substrate; forming a plurality of gate lines on the first substrate; forming a gate covering layer on the first substrate and covering the gate lines; forming a plurality of data lines on the gate covering layer; forming a first protection layer on the gate covering layer and covering the data lines; sequentially forming a plurality of photoresist layers disposed in parallel on the first protection layer, to complete a plurality of CFs; forming a second protection layer on the CFs and covering the first protection layer; forming a plurality of light spacers on the second protection layer; forming a pixel electrode layer on the second protection layer; and forming an opaque matrix layer on an outer surface of the first substrate and shielding the gate lines.

In an embodiment of this application, in the manufacturing method, the step of forming a plurality of light spacers on the second protection layer comprises: forming a light shielding material layer on the second protection layer, to cover the second protection layer; disposing a mask on the light shielding material layer, where the mask has a transparent region, an opaque region, and a semi-transparent region; and performing exposure manufacturing and development manufacturing, to pattern the light shielding material layer to form the light spacers.

In an embodiment of this application, in the manufacturing method, the light spacers all include at least two types of steps formed by using a same mask.

In an embodiment of this application, in the manufacturing method, the mask is a gray-scale mask or a half tone mask.

Still another objective of this application is to provide an LCD panel, comprising: an active switch array substrate, an opposite substrate, a transparent electrode layer, and a liquid crystal layer. The active switch array substrate comprises: a first substrate, having an outer surface, where the outer surface has a black adhesive material; a plurality of gate lines, formed on the first substrate; a gate covering layer, formed on the first substrate and covering the gate lines; a plurality of data lines, formed on the gate covering layer; a first protection layer, formed on the gate covering layer and covering the data lines; a plurality of CFs, formed on the first protection layer and comprising a plurality of photoresist layers disposed in parallel; a second protection layer, formed on the CFs and covering the first protection layer; a pixel electrode layer, formed on the second protection layer; a plurality of light spacers, formed on the second protection layer and connected to the second protection layer; and an opaque matrix layer, formed on the outer surface of the first substrate, where the opaque matrix layer shields the gate lines. The opposite substrate comprises a second substrate, where the active switch array substrate is disposed opposite to the opposite substrate, and the light spacers are located between the opposite substrate and the active switch array substrate, to define a liquid crystal separation space. The transparent electrode layer is disposed on the second substrate. The liquid crystal layer is located between the active switch array substrate and the opposite substrate and filling the liquid crystal separation space. The LCD panel further comprises a fiber material layer disposed between the active switch array substrate and the opposite substrate.

Yet another objective of this application is to provide an LCD device, comprising a backlight module, and further comprising the LCD panel.

In this application, MM of a displayed image and an alignment accuracy error of upper and lower substrate glasses may be reduced.

### BRIEF DESCRIPTION OF THE DRAWINGS

FIG. 1a is a schematic cross-sectional view of an exemplary liquid crystal panel including an active switch array substrate having an RGB photoresist layer and an opaque matrix layer;

FIG. 1b is a schematic cross-sectional view of an exemplary in-plane switching liquid crystal panel including an active switch array substrate having an RGB photoresist layer;

FIG. 1c is another schematic cross-sectional view of an exemplary vertical alignment liquid crystal panel including an active switch array substrate having an RGB photoresist layer;

FIG. 2a is a schematic cross-sectional view of an active switch array substrate applied to a peripheral region of an LCD panel according to a method of this application;

FIG. 2b is a schematic cross-sectional view of an active switch array substrate applied to a display region of an LCD panel according to a method of this application;

FIG. 2c is a schematic cross-sectional view of an active switch array substrate applied to another peripheral region of an LCD panel according to a method of this application;

FIG. 2d is a schematic cross-sectional view of an active switch array substrate applied to an LCD panel according to a method of this application;

FIG. 3a is a schematic diagram of a glass surface of a CF substrate in an exemplary LCD;

FIG. 3b is a schematic diagram of an active switch array substrate applied to an LCD and having an opaque matrix layer and a black adhesive material in a backside according to a method of this application; and

FIG. 3c is a schematic diagram of attaching a black adhesive material to a backside of an active switch array substrate by means of ink jetting or ultraviolet irradiation.

### DETAILED DESCRIPTION

The following embodiments are described with reference to the accompanying drawings, which are used to exemplify specific embodiments for implementation of this application. Terms about directions mentioned in this application, such as “on”, “below”, “front”, “back”, “left”, “right”, “in”, “out”, and “side surface” merely refer to directions in the accompanying drawings. Therefore, the used terms about directions are used to describe and understand this application, and are not intended to limit this application.

The accompanying drawings and the description are considered to be essentially exemplary, rather than limitative. In the figures, units with similar structures are represented by using the same reference number. In addition, for understanding and ease of description, the size and the thickness of each component shown in the accompanying drawings are arbitrarily shown, but this application is not limited thereto.

In the accompanying drawings, for clarity, thicknesses of a layer, a film, a panel, an area, and the like are enlarged. In the accompanying drawings, for understanding and ease of description, thicknesses of some layers and areas are enlarged. It should be understood that when a component such as a layer, a film, an area, or a base is described to be “on” “another component”, the component may be directly on the another component, or there may be an intermediate component.

In addition, in this specification, unless otherwise explicitly described to have an opposite meaning, the term “include” is understood as including the component, but not excluding any other component. In addition, in this specification, “on” means that a component is located on or below a target component, but does not mean that the component needs to be located on top of the gravity direction.

To further describe the technical means adopted in this application to achieve the intended application objective and effects thereof, specific implementations, structures, features, and effects of an active switch array substrate, a method for manufacturing an active switch array substrate, and a display device using same provided according to this application are described below in detail with reference to the drawings and preferred embodiments.

An LCD panel in this application may include: an active switch array (Thin Film Transistor, TFT) substrate, a CF substrate, and a liquid crystal layer formed between the two substrates.

In an embodiment, the LCD panel in this application may be a curved display panel.

In an embodiment, the active switch array (TFT) and the CF in this application may be formed on a same substrate.

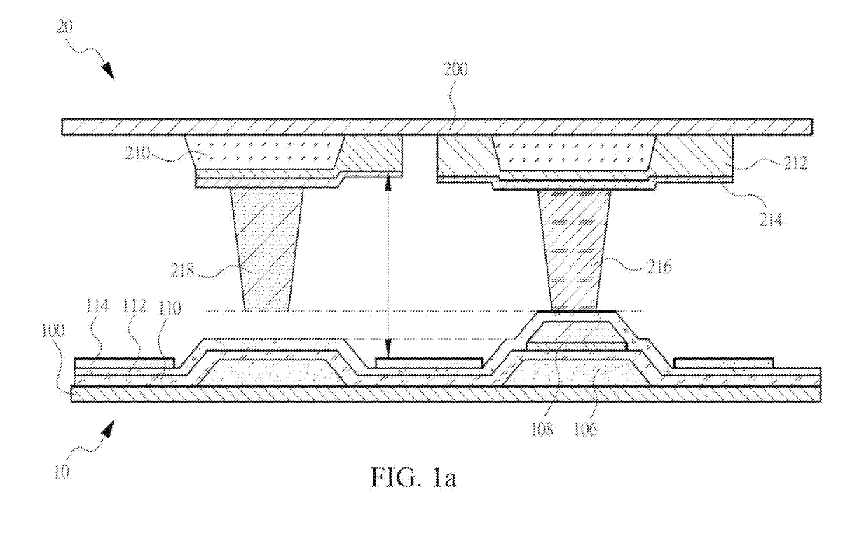

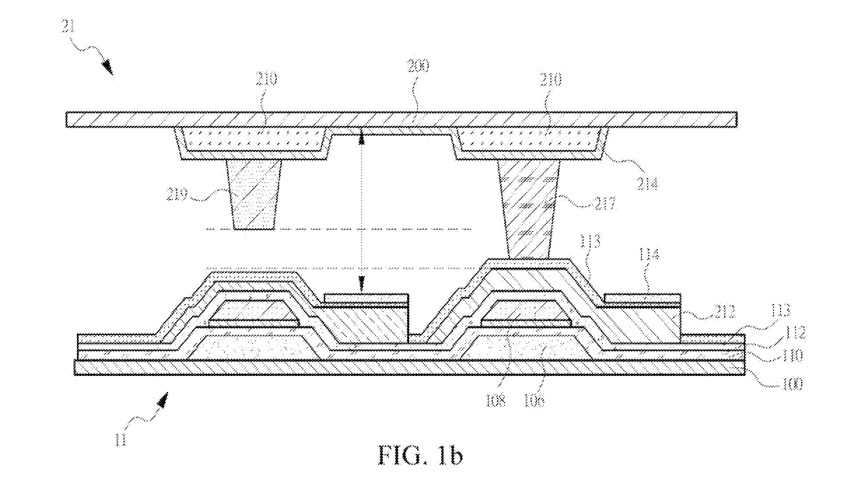

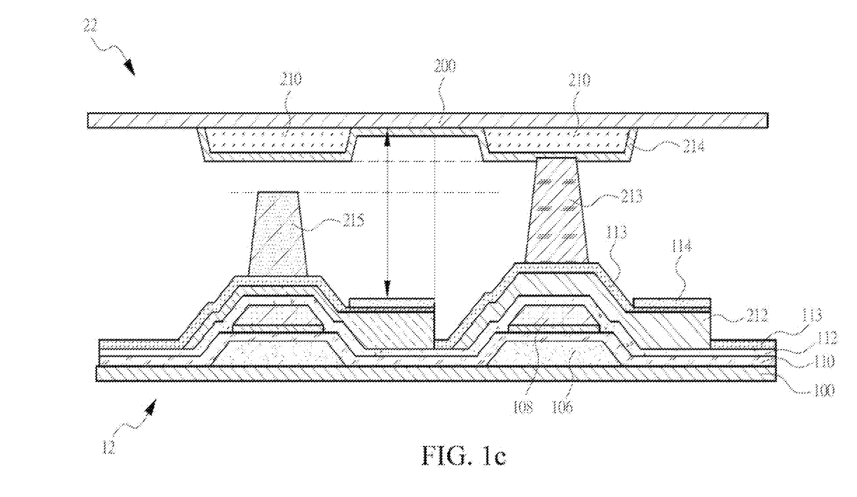

FIG. 1a is a schematic cross-sectional view of an exemplary liquid crystal panel including an active switch array substrate having an RGB photoresist layer and an opaque matrix layer. Referring to FIG. 1a, a liquid crystal panel having an active switch array substrate having an RGB photoresist layer and an opaque matrix layer includes: an opposite substrate 20, an active switch array substrate 10, and a liquid crystal layer. The opposite substrate 20 includes: a second substrate 200; a CF 212, disposed on the second substrate 200 and including a plurality of photoresist layers (each includes a red photoresist, a green photoresist, and a blue photoresist) disposed in parallel; an opaque matrix layer 210, disposed on the second substrate 200; an indium tin oxide electrode layer 214, disposed on the CF 212; and a plurality of light spacers 216 and 218, disposed on the indium tin oxide electrode layer 214. The active switch array substrate 10 includes: a first substrate 100, where the active switch array substrate 10 is disposed opposite to the opposite substrate 20, the light spacers 216 and 218 are located between the opposite substrate 20 and the active switch array substrate 10, to define a liquid crystal separation space; a plurality of gate lines 106, formed on the first substrate 100; a gate covering layer 110, formed on the first substrate 100 and covering the gate lines 106; a plurality of data lines 108, formed on the gate covering layer 110, where the data lines 108 and the gate lines 106 define a plurality of pixel regions; a first protection layer 112, formed on the gate covering layer 110 and covering the data lines 108; and a pixel electrode layer 114, formed on the first protection layer 112. The liquid crystal layer (not shown in the figure) is located between the opposite substrate 20 and the active switch array substrate 10 and fills the liquid crystal separation space.

FIG. 1b is a schematic cross-sectional view of an exemplary in-plane switching liquid crystal panel including an active switch array substrate having an RGB photoresist layer. Referring to FIG. 1b, an in-plane switching liquid crystal panel including an active switch array substrate having an RGB photoresist layer includes: an active switch array substrate 11, an opposite substrate 21, and a liquid crystal. The active switch array substrate includes: a first substrate 100; a plurality of gate lines 106, formed on the first substrate 100; a gate covering layer 110, formed on the first substrate 100 and covering the gate lines 106; a plurality of data lines 108, formed on the gate covering layer 110, where the data lines 108 and the gate lines 106 define a plurality of pixel regions; a first protection layer 112, formed on the gate covering layer 110 and covering the data lines 108; a CF 212, formed on the first protection layer 112 and including a plurality of photoresist layers (each includes a red photoresist, a green photoresist, and a blue photoresist) disposed in parallel; a second protection layer 113, formed on the CF 212 and covering the first protection layer 112; and a pixel electrode layer 114, formed on the second protection layer 113. The opposite substrate 21 includes: a second substrate 200; an opaque matrix layer 210, disposed on the second substrate 200; an indium tin oxide electrode layer 214, disposed on the second substrate 200 and covering the opaque matrix layer 210; and a plurality of light spacers 217 and 219, disposed on the indium tin oxide electrode layer 214, where the active switch array substrate 11 is disposed opposite to the opposite substrate 21, and the light spacers 217 and 219 are located between the opposite substrate 21 and the active switch array substrate 11, to define a liquid crystal separation space. The liquid crystal layer (not shown in the figure) is located between the opposite substrate 21 and the active switch array substrate 11 and fills the liquid crystal separation space.

FIG. 1c is another schematic cross-sectional view of an exemplary vertical alignment liquid crystal panel including an active switch array substrate having an RGB photoresist layer. Referring to FIG. 1c, a vertical alignment liquid crystal panel including an active switch array substrate having an RGB photoresist layer includes: an active switch array substrate 12, an opposite substrate 22, and a liquid crystal layer. The active switch array substrate 12 includes: a first substrate 100; a plurality of gate lines 106, formed on the first substrate 100; a gate covering layer 110, formed on the first substrate 100 and covering the gate lines 106; a plurality of data lines 108, formed on the gate covering layer 110, where the data lines 108 and the gate lines 106 define a plurality of pixel regions; a first protection layer 112, formed on the gate covering layer 110 and covering the data lines 108; a CF 212, formed on the first protection layer 112 and including a plurality of photoresist layers (each includes a red photoresist, a green photoresist, and a blue photoresist) disposed in parallel; a second protection layer 113, formed on the CF 212 and covering the first protection layer 112; a pixel electrode layer 114, formed on the second protection layer 113; and a plurality of light spacers 213 and 215, formed on the second protection layer 113 and connected to the second protection layer 113. The opposite substrate 22 includes: a second substrate 200; an opaque matrix layer 210, disposed on the second substrate 200; and an indium tin oxide electrode layer 214, disposed on the second substrate 200 and covering the opaque matrix layer 210, where the active switch array substrate 12 is disposed opposite to the opposite substrate 22, and the light spacers 213 and 215 are located between the opposite substrate 22 and the active switch array substrate 12, to define a liquid crystal separation space. The liquid crystal layer (not shown in the figure) is located between the opposite substrate 22 and the active switch array substrate 12 and fills the liquid crystal separation space.

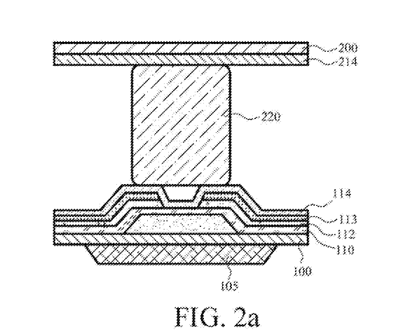

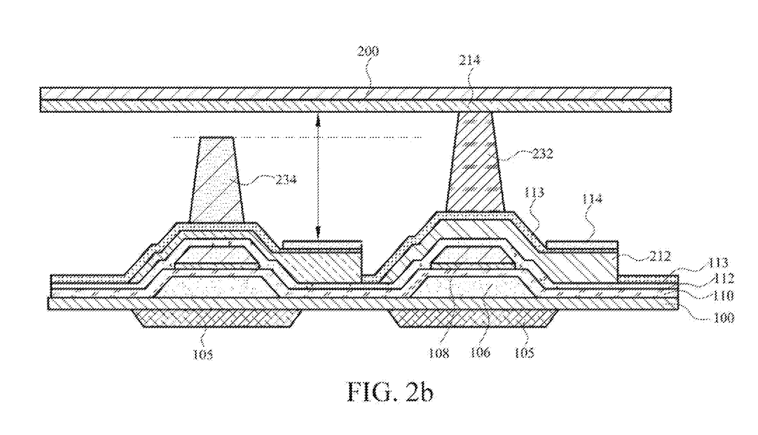

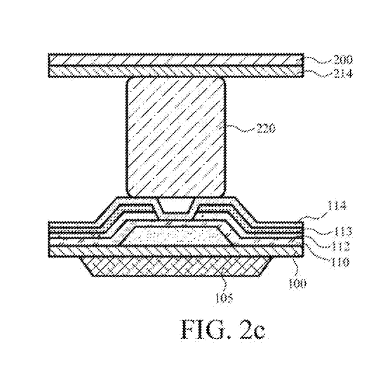

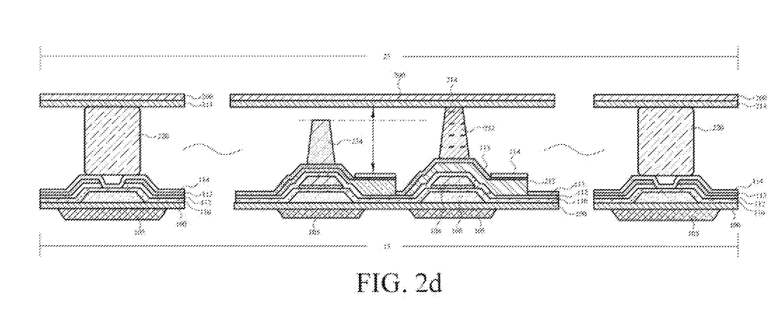

FIG. 2a is a schematic cross-sectional view of an active switch array substrate applied to a peripheral region of an LCD panel according to a method of this application. FIG. 2b is a schematic cross-sectional view of an active switch array substrate applied to a display region of an LCD panel according to a method of this application. FIG. 2c is a schematic cross-sectional view of an active switch array substrate applied to another peripheral region of an LCD panel according to a method of this application. FIG. 2d is a schematic cross-sectional view of an active switch array substrate applied to an LCD panel according to a method of this application. Referring to FIG. 2a, FIG. 2b, FIG. 2c, and FIG. 2d, in an embodiment of this application, an active switch array substrate 13 includes: a first substrate 100; a plurality of gate lines 106, formed on the first substrate 100; a gate covering layer 110, formed on the first substrate 100 and covering the gate lines 106; a plurality of data lines 108, formed on the gate covering layer 110, where the data lines 108 and the gate lines 106 define a plurality of pixel regions; a first protection layer 112, formed on the gate covering layer 110 and covering the data lines 108; a CF 212, formed on the first protection layer 112 and including a plurality of photoresist layers (each includes a red photoresist, a green photoresist, and a blue photoresist) disposed in parallel; a second protection layer 113, formed on the CF 212 and covering the first protection layer 112; a pixel electrode layer 114, formed on the second protection layer 113; a plurality of light spacers 232 and 234, formed on the second protection layer 113 and connected to the second protection layer 113; and an opaque matrix layer 105, formed on an outer surface of the first substrate 100, where the opaque matrix layer 105 shields the gate lines 106.

In an embodiment, the opaque matrix layer 105 is made of an insulating black ink.

In an embodiment, the light spacers 232 and 234 have a protrusion shape with a narrow top and a wide bottom.

In an embodiment, a black adhesive material of the outer surface of the first substrate 100 is the same as a material of the opaque matrix layer 105, to cover a frame circuit.

In an embodiment, a peripheral region of the active switch array substrate 13 includes a fiber material layer 220 located between the active switch array substrate 13 and the opposite substrate 23.

Referring to FIG. 2a, FIG. 2b, FIG. 2c, and FIG. 2d, in an embodiment of this application, an LCD panel includes: an active switch array substrate 13, an opposite substrate 23, and a liquid crystal layer. The active switch array substrate 13 includes: a first substrate 100; a plurality of gate lines 106, formed on the first substrate 100; a gate covering layer 110, formed on the first substrate 100 and covering the gate lines 106; a plurality of data lines 108, formed on the gate covering layer 110, where the data lines 108 and the gate lines 106 define a plurality of pixel regions; a first protection layer 112, formed on the gate covering layer 110 and covering the data lines 108; a CF 212, formed on the first protection layer 112 and including a plurality of photoresist layers (each includes a red photoresist, a green photoresist, and a blue photoresist) disposed in parallel; a second protection layer 113, formed on the CF 212 and covering the first protection layer 112; a pixel electrode layer 114, formed on the second protection layer 113; a plurality of light spacers 232 and 234, formed on the second protection layer 113 and connected to the second protection layer 113; and an opaque matrix layer 105, formed on an outer surface of the first substrate 100, where the opaque matrix layer 105 shields the gate lines 106. The opposite substrate 23 includes a second substrate 200, where the active switch array substrate 13 is disposed opposite to the opposite substrate 23, the light spacers 232 and 234 are located between the opposite substrate 23 and the active switch array substrate 13, to define a liquid crystal separation space, and a transparent electrode layer 214 is disposed on the second substrate 200. The liquid crystal layer is located between the active switch array substrate 13 and the opposite substrate 23 and fills the liquid crystal separation space.

In an embodiment, the opaque matrix layer 105 is made of an insulating black ink.

In an embodiment, the light spacers 232 and 234 have a protrusion shape with a narrow top and a wide bottom.

In an embodiment, a black adhesive material of the outer surface of the first substrate 100 is the same as a material of the opaque matrix layer 105, to cover a frame circuit.

In an embodiment, a peripheral region of the active switch array substrate 13 includes a fiber material layer 220 located between the active switch array substrate 13 and the opposite substrate 23.

Referring to FIG. 2a, FIG. 2b, FIG. 2c, and FIG. 2d, in an embodiment of this application, an LCD device includes a backlight module, and further includes: an active switch array substrate 13, an opposite substrate 23, a transparent electrode layer 214, and a liquid crystal layer. The active switch array substrate 13 includes: a first substrate 100; a plurality of gate lines 106, formed on the first substrate 100; a gate covering layer 110, formed on the first substrate 100 and covering the gate lines 106; a plurality of data lines 108, formed on the gate covering layer 110, where the data lines 108 and the gate lines 106 define a plurality of pixel regions; a first protection layer 112, formed on the gate covering layer 110 and covering the data lines 108; a CF 212, formed on the first protection layer 112 and including a plurality of photoresist layers (each includes a red photoresist, a green photoresist, and a blue photoresist) disposed in parallel; a second protection layer 113, formed on the CF 212 and covering the first protection layer 112; a pixel electrode layer 114, formed on the second protection layer 113; a plurality of light spacers 232 and 234, formed on the second protection layer 113 and connected to the second protection layer 113; and an opaque matrix layer 105, formed on an outer surface of the first substrate 100, where the opaque matrix layer 105 shields the gate lines 106. The opposite substrate 23 includes a second substrate 200, where the active switch array substrate 13 is disposed opposite to the opposite substrate 23, and the light spacers 232 and 234 are located between the opposite substrate 23 and the active switch array substrate 13, to define a liquid crystal separation space. The transparent electrode layer 214 is disposed on the second substrate 200. The liquid crystal layer is located between the active switch array substrate 13 and the opposite substrate 23 and fills the liquid crystal separation space.

In an embodiment, the opaque matrix layer 105 is made of an insulating black ink.

In an embodiment, the light spacers 232 and 234 have a protrusion shape with a narrow top and a wide bottom.

In an embodiment, a black adhesive material of the outer surface of the first substrate 100 is the same as a material of the opaque matrix layer 105, to cover a frame circuit.

In an embodiment, a peripheral region of the active switch array substrate 13 includes a fiber material layer 220 located between the active switch array substrate 13 and the opposite substrate 23.

Referring to FIG. 2a, FIG. 2b, FIG. 2c, and FIG. 2d, in an embodiment of this application, a method for manufacturing an active switch array substrate 13 includes: providing a first substrate 100; forming a plurality of gate lines 106 on the first substrate 100; forming a gate covering layer 110 on the first substrate 100 and covering the gate lines 106; forming a plurality of data lines 108 on the gate covering layer 110, where the data lines 108 and the gate lines 106 define a plurality of pixel regions; forming a first protection layer 112 on the gate covering layer 110 and covering the data lines 108; sequentially forming a plurality of photoresist layers (each includes a red photoresist, a green photoresist, and a blue photoresist) disposed in parallel on the first protection layer 112, to complete a CF 212; forming a second protection layer 113 on the CF 212 and covering the first protection layer 112; forming a plurality of light spacers 232 and 234 on the second protection layer 113; forming a pixel electrode layer 114 on the second protection layer 113; and forming an opaque matrix layer 105 on an outer surface of the first substrate 100 and shielding the gate lines 106.

In an embodiment, in the manufacturing method, the step of forming a plurality of light spacers 232 and 234 on the second protection layer 113 includes: forming a light shielding material layer on the second protection layer 113, to cover the second protection layer 113; and disposing a mask on the light shielding material layer, where the mask has a transparent region, an opaque region, and a semi-transparent region; and performing exposure manufacturing and development manufacturing, to pattern the light shielding material layer to form the light spacers 232 and 234.

In an embodiment, in the manufacturing method, the light spacers 232 and 234 all include at least two types of steps formed by using a same mask.

In an embodiment, in the manufacturing method, the mask is a gray-scale mask or a half tone mask.

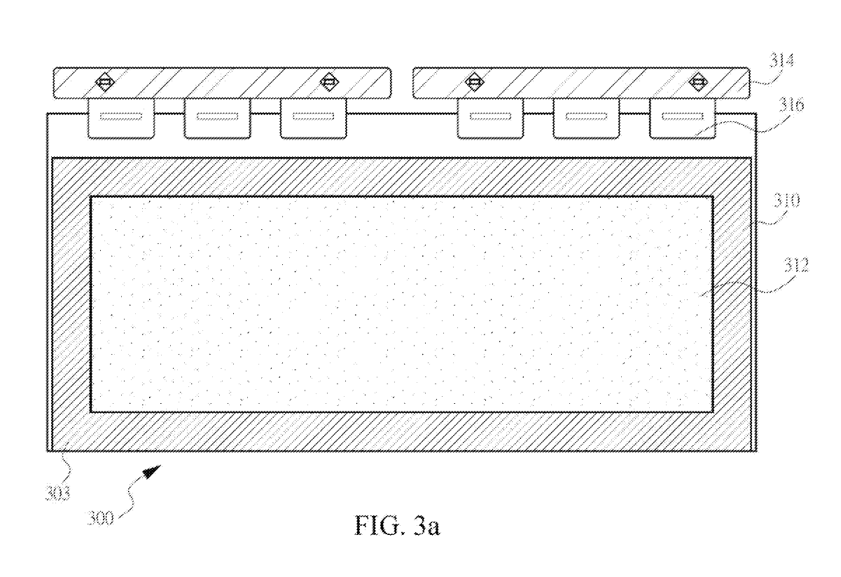

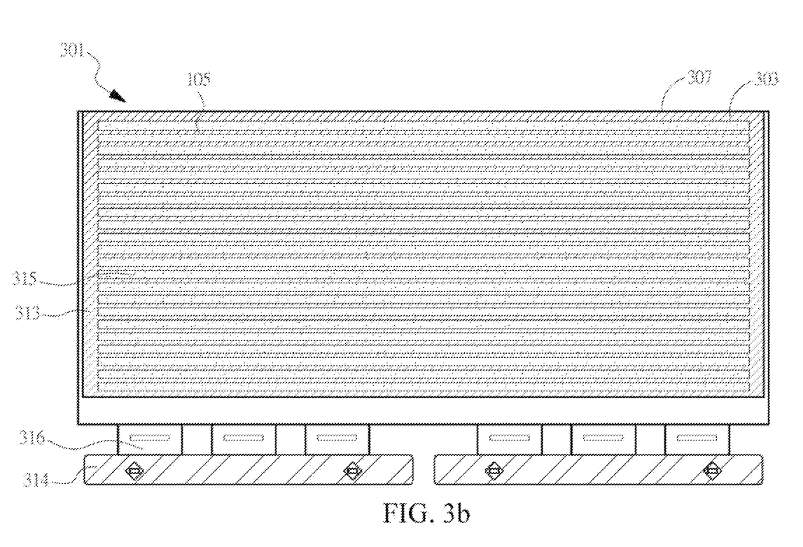

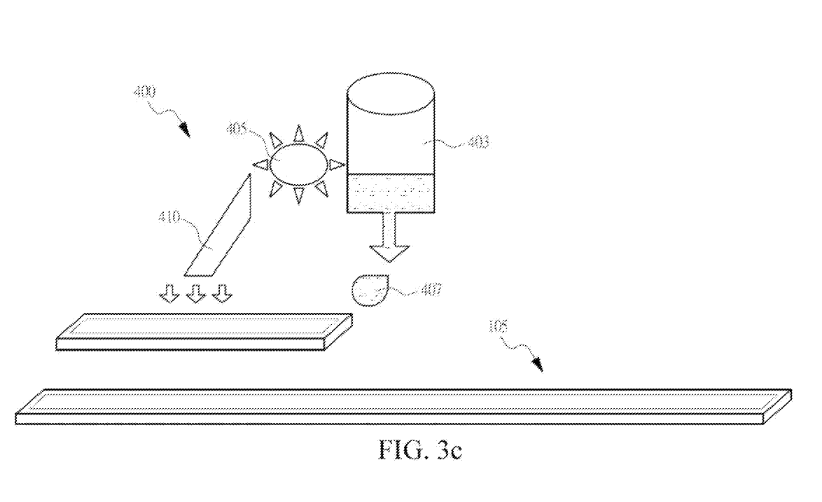

FIG. 3a is a schematic diagram of a glass surface of a CF substrate in an exemplary LCD. Referring to FIG. 3a, an LCD 300 includes: a black photoresist material 310, a CF substrate glass 312, a base 314, and a support 316. The support 316 is connected to the base 314, and the black photoresist material 310 is attached to an edge 303 of the CF substrate glass 312.

In an embodiment, the CF substrate glass 312 faces upward.

FIG. 3b is a schematic diagram of an active switch array substrate applied to an LCD and having an opaque matrix layer and a black adhesive material in a backside according to a method of this application. Referring to FIG. 2b, FIG. 2d, and FIG. 3b, in an embodiment of this application, a bezel-less LCD 301 includes: a black adhesive material 313, an active switch array substrate glass 315, a base 314, and a support 316. The support 316 is connected to the base 314, the black adhesive material 313 is attached to an edge 303 of the active switch array substrate glass 315 and a backside 307, and a display region of the active switch array substrate glass 315 has a black matrix layer 105.

In an embodiment, the active switch array substrate glass 315 faces upward.

FIG. 3c is a schematic diagram of attaching a black adhesive material to a backside of an active switch array substrate by means of ink jetting or ultraviolet irradiation. Referring to FIG. 2b, FIG. 2d, FIG. 3b, and FIG. 3c, in an embodiment of this application, an ink jetting device 400 includes: a unit 403 for allocating a black adhesive material, an ultraviolet irradiation light emitting unit 405, an ultraviolet beam 410, and a black adhesive material 407. The allocation unit 403 of the black adhesive material coats the black adhesive material 407 on a backside 307 of the active switch array substrate glass 315 by means of ink jetting, the black adhesive material 407 is cured on a black matrix layer 105 or the backside 307 of the active switch array substrate glass 315 by using the ultraviolet beam 410 emitted by the ultraviolet irradiation light emitting unit 405.

A multi-tone mask may include a gray-tone mask and a half tone mask. The gray-tone mask manufactures a silt lower than a resolution of an exposure device, and covers a part of a light source by using the silt part, to achieve half exposure. On the other hand, the half tone mask performs half exposure by using a “translucent” film. Because in the foregoing two manners, three exposure levels, namely, exposed part, half-exposed part and unexposed part, are presented after one exposure process, photoresists having two types of thicknesses can be formed after development (by using such a thickness difference of the photoresists, a graphic may be transferred onto a panel substrate of a quantity less than a usual quantity, and production efficiency of the panel is improved) is performed. If the multi-tone mask is a half tone mask, costs of the mask are slightly higher than costs of a common mask.

In this application, MM of a displayed image and an alignment accuracy error of upper and lower substrate glasses may be reduced.

The terms such as “in some embodiments” and “in various embodiments” are repeatedly used. The terms usually refer to different embodiments, but they may also refer to a same embodiment. The terms such as “comprising”, “having” and “including” are synonyms, unless other meanings are indicated by the context.

Descriptions above are merely preferred embodiments of this application, and are not intended to limit this application. Although this application has been disclosed above through the preferred embodiments, the embodiments are not intended to limit this application. A person skilled in the art can make some equivalent variations, alterations or modifications to the above-disclosed technical content without departing from the scope of the technical solutions of this application to obtain equivalent embodiments. Any simple alteration, equivalent change or modification made to the above embodiments according to the technical essence of this application without departing from the content of the technical solutions of this application shall fall within the scope of the technical solutions of this application.

What is claimed is:

1. An active switch array substrate, comprising:
a first substrate, having an outer surface, wherein the outer surface has a black adhesive material;
a plurality of gate lines, formed on the first substrate;
a gate covering layer, formed on the first substrate and covering the gate lines;
a plurality of data lines, formed on the gate covering layer;
a first protection layer, formed on the gate covering layer and covering the data lines;
a plurality of color filters (CFs), formed on the first protection layer and comprising a plurality of photoresist layers disposed in parallel;
a second protection layer, formed on the CFs and covering the first protection layer;
a pixel electrode layer, formed on the second protection layer;
a plurality of light spacers, formed on the second protection layer and connected to the second protection layer; and
an opaque matrix layer, formed on the outer surface of the first substrate, wherein the opaque matrix layer shields the gate lines.

2. The active switch array substrate according to claim 1, wherein the opaque matrix layer is made of an insulating black ink.

3. The active switch array substrate according to claim 1, wherein the light spacer has a protrusion shape with a narrow top and a wide bottom.

4. The active switch array substrate according to claim 1, wherein the black adhesive material of the outer surface of the first substrate is the same as the material of the opaque matrix layer.

5. The active switch array substrate according to claim 1, wherein the black adhesive material covers a frame circuit.

6. A method for manufacturing an active switch array substrate, comprising:
providing a first substrate;
forming a plurality of gate lines on the first substrate;
forming a gate covering layer on the first substrate and covering the gate lines;
forming a plurality of data lines on the gate covering layer;
forming a first protection layer on the gate covering layer and covering the data lines;
sequentially forming a plurality of photoresist layers disposed in parallel on the first protection layer, to complete a plurality of color filters (CFs);
forming a second protection layer on the CF and covering the first protection layer;
forming a plurality of light spacers on the second protection layer;
forming a pixel electrode layer on the second protection layer; and
forming an opaque matrix layer on the outer surface of the first substrate and shielding the gate lines.

7. The method for manufacturing an active switch array substrate according to claim 6, wherein the step of forming a plurality of light spacers on the second protection layer comprises:
forming a light shielding material layer on the second protection layer, to cover the second protection layer;
disposing a mask on the light shielding material layer, wherein the mask has a transparent region, an opaque region, and a semi-transparent region; and
performing exposure manufacturing and development manufacturing, to pattern the light shielding material layer to form the light spacers.

8. The method for manufacturing an active switch array substrate according to claim 6, wherein the light spacers all include at least two types of steps formed by using a same mask.

9. The method for manufacturing an active switch array substrate according to claim 8, wherein the mask is a gray-scale mask.

10. The method for manufacturing an active switch array substrate according to claim 8, wherein the mask is a halftone mask.

11. A liquid crystal display (LCD) device, comprising:
a backlight module; and
a display panel, comprising:
an active switch array substrate, comprising:
a first substrate, having an outer surface, wherein the outer surface has a black adhesive material;
a plurality of gate lines, formed on the first substrate;
a gate covering layer, formed on the first substrate and covering the gate lines;
a plurality of data lines, formed on the gate covering layer;
a first protection layer, formed on the gate covering layer and covering the data lines;
a plurality of color filters (CFs), formed on the first protection layer and comprising a plurality of photoresist layers disposed in parallel;
a second protection layer, formed on the CF and covering the first protection layer;
a pixel electrode layer, formed on the second protection layer;
a plurality of light spacers, formed on the second protection layer and connected to the second protection layer; and
an opaque matrix layer, formed on the outer surface of the first substrate, wherein the opaque matrix layer shields the gate lines;
an opposite substrate, comprising a second substrate, wherein the active switch array substrate is disposed opposite to the opposite substrate, and the light spacers are located between the opposite substrate and the active switch array substrate, to define a liquid crystal separation space; and
a transparent electrode layer, disposed on the second substrate; and
a liquid crystal layer, located between the active switch array substrate and the opposite substrate and filling the liquid crystal separation space, and
a material of the opaque matrix layer is an insulating black ink.

12. The LCD device according to claim 11, wherein the black adhesive material of the outer surface of the first substrate is the same as the material of the opaque matrix layer.

13. The LCD device according to claim 12, wherein the black adhesive material covers a frame circuit.

14. The LCD device according to claim 11, further comprising a fiber material layer disposed between the active switch array substrate and the opposite substrate.
